(19) United States
(12) Patent Application Publication
(10) Pub. No.: US 2007/0240981 A1
(43) Pub. Date: Oct. 18, 2007

(54) Sputter Target With High-Melting Phase

(75) Inventors: Martin SCHLOTT, Offenbach (DE); Markus SCHULTHEIS, Flieden (DE)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: W. C. HERAEUS GMBH, Hanau (DE)

(21) Appl. No.: 11/625,080

(22) Filed: Jan. 19, 2007

(30) Foreign Application Priority Data
Jan. 23, 2006 (DE) 10 2006 003 279.9

(51) Int. Cl. C23C 14/00

(52) U.S. Cl. 204/298.13; 420/492; 420/505

(57) ABSTRACT

A sputter target is made of a material comprising at least two phases or components, wherein at least one minor phase has low solubility in the matrix and has a higher melting point than the matrix. The at least one minor phase has a mean particle size of 10 μm maximum of its grains or of agglomerates formed by its grains, and the material has a density of at least 98% of its theoretical density.

### BACKGROUND OF THE INVENTION

This invention relates to a sputter target of a material comprising at least two phases or components, wherein at least one minor phase has low solubility in the matrix and has a higher melting point than the matrix.

For the manufacture of TFT LCD displays, powder-metallurgical mixtures, as well as alloys with deposits of a second phase, have recently been increasingly used as so-called sputter targets—aside from single-component materials, such as Al, Ti, Mo, and Cr (see, for example, European patent application publication EP 1 559 801). This vacuum coating method has so far predominantly used single-component sputter targets to produce the corresponding layers (e.g., for structuring source, drain and gate contacts, or for reflective/semi-reflective applications). As long as the second phase has a high melting point and a low or infinitesimal solubility in the major component, only powder-metallurgical production methods will remain for the corresponding sputter targets. Preferred powder-metallurgical methods are sintering; sintering and subsequent rolling; hot isostatic pressing and sawing of large blocks; or hot isostatic pressing and subsequent reforming to plates or tubes.

In the manufacture of TFT displays, it is very important that the sputter targets do not release any particles, since this might result in the failure of individual pixels. With regard to multi-component sputter targets with greatly varying melting points or sputter rates, the problem exists that the high-melting phase results in elevations due to the low sputter rate, as compared to the matrix with a high sputter rate. Depending on the material combination, these elevations can increase to cones or nodules until they rupture at a certain size due to thermal stress or a short discharge (arc) and release particles.

### BRIEF SUMMARY OF THE INVENTION

Accordingly, it is the object of this invention to develop sputter targets on the basis of different multi-component or multi-phase materials, i.e., those not forming any “genuine” alloys or mixed crystals (e.g., for TFT display coating)—whose structure is designed such that in erosion during sputtering, no particles will form, if at all possible, which would diminish the product yield.

The structure of the at least one minor phase is, in this case, characterized by grains or by agglomerates formed of grains with a mean size of 10 μm maximum, preferably 5 μm maximum, in particular 1 μm maximum; and the material has a density of at least 98%, preferably at least 99% of its theoretical density. A minor component is also called a minor phase; a main or major component is also called a main phase, a component designating undissolved phase parts. The main phase or the main component forms the matrix. Low solubility phases are those whose solubility is at least 3 to 5 times lower than their weight portion in relation to the matrix, so that—in thermal equilibrium at room temperature—the predominant part of the phase/component is present in the form of deposits. Moreover, the solubility of the minor phase in the matrix should not be higher than approx. 1% overall.

Advantageously, the at least one minor phase has a melting point which is higher than the matrix by at least about 500° C., preferably by at least about 1,000° C. higher. It is expedient that the material contain metals from the group of W, Mo, Ta, Nb, Cr, V, Ti, Cu, Ni, Al, Ag, Au, Pt, Ru. It is advantageous that the material be formed on the basis of Cu, Ag or Al as the matrix, and that the at least one low soluble phase contain at least one of the elements Cr, Mo, W, Ti, and/or Ru.

The percentage of the component of at least one minor phase in the material preferably amounts to at least about 0.5% by weight. The total percentage of the component of the at least one minor phase in the matrix material preferably amounts to a maximum of about 10% by weight.

### DETAILED DESCRIPTION OF THE INVENTION

One method according to the invention for the manufacture of sputter targets is wherein a mixture is produced from powder in a first step, such that the minor component(s) will be finely dispersed, so that preferably no or only very small agglomerates are present and that the particles of the at least one minor phase have a mean particle size (largest dimension) of 10 μm maximum, preferably 5 μm maximum, in particular 1 μm maximum. From this powder mixture, a planar or tubular sputter target will then be produced via known production methods, such as sintering and rolling, HIP and sawing, or HIP and reforming.

It was thus found that it is possible to suppress the formation of nodules or cones on the sputter target or at least reduce it substantially, when a “monodisperse” powder of a sufficiently fine grain size is used for the minor phase(s) and the powder mix is subsequently conventionally compacted to >98% density.

To coat large-format substrates, e.g., for TFT-LCD screens, it is thus possible to produce sputter targets having a low particle formation rate and a high density in the form of plates or tubes on the basis of multi-phase materials—preferably on the basis of W, Mo, Ta, Nb, Cr, V, Ti, Cu, Ni, Al, Ag, Au, Pt, Ru, especially Cu:Mo, Cu:W, Ag:Cr, Ag:Mo, Ag:W, Ag:Ti. Analogously to Examples 1 and 2 below, the following alloy compositions can be produced, for example: Cu:Cr, Cu:W, Cu:Ru, Cu:Ti, Ag:Mo, Ag:W, Ag:Ti, or Ag:Ru, wherein the minor phase alloy portion (Mo, W, Cr, Ti, or Ru) is present in a range of less than 10% by weight each.

Exemplary, non-limiting embodiments of the invention are described in the following for purposes of illustration only.

### EXAMPLE 1

A powder mix of 99% by weight of Ag and 1% by weight of a very fine Cr powder having a mean grain size of 7 μm was intensively mixed in an impeller mixer, so that a fine and monodisperse distribution of the Cr particles in the Ag major phase resulted. Subsequently, this mixture was first pressed by cold isostatic pressing to a cylindrical block with Dₐ=300 mm and L=400 mm. This cylinder was machined to form a hollow cylinder with Dₐ=300 mm, Dᵢ=120 mm. The resulting hollow cylinder was reformed by extrusion at 500° C. to a tubular blank with Dₐ=157 mm and Dᵢ=122 mm. The resulting reformed structure presented a matrix of Ag grains in which individual, completely de-agglomerated Cr particles having a mean grain size of 7 μm were embedded. From the tube thus formed, a monolithic (i.e., no carrier tube) target tube was machined with the dimensions Dₐ=153 mm, Dᵢ=124 mm and L=2400 mm, and was tested in sputter operation. The result was a very smooth erosion zone and an extremely low particle sputter operation.

### EXAMPLE 2

A powder mix of 97% by weight of Cu and 3% by weight of a very fine Mo powder having a mean grain size of 3 μm was intensively mixed in an impeller mixer, so that a fine and monodisperse distribution of the Mo particles in the Cu major phase resulted. Subsequently, this mixture was first pressed by cold isostatic pressing to a rectangular block with a cross-section of 50×100 mm and a length of L=400 mm. Subsequently, the block was compacted by HIP at 750° C. and 1,000 bar to more than 99% of its theoretical density. The structure consisted of a Cu matrix in which individual, completely de-agglomerated Mo particles having a mean grain size of 3 μm were embedded. In only very isolated cases, small parts of 2 to 3 particles were also encountered. From the block thus formed, a target plate of 88×350 mm edge length was produced and tested in sputter operation. The result was a very smooth erosion zone and a nearly particle-free sputter operation.

### COMPARATIVE EXAMPLE 1

A powder mix of 96% by weight of Cu and 4% by weight of W powder having a mean grain size of 40 cm was processed analogously to Example 2. The structure consisted of the Cu matrix in which individual W particles of typically 40 μm size were integrated. In sputtering, a very rough surface resulted which was coated by innumerable cones/nodules. After a certain period of time (approx. 20% of the life of the target), the target began to increasingly release particles, so that it became unsuitable for the coating of, for example, TFT substrates or other electronic circuitry.

### COMPARATIVE EXAMPLE 2

A powder mix of 99% by weight of Ag and 1% by weight of a highly agglomerated Mo powder with a mean primary particle size of 4 μm and up to 100 μm large agglomerates were mixed in a tumble mixer. Subsequently, the mixture was first pressed by cold isostatic pressing to a cuboidal block having 60 mm×120 mm×500 mm edge length. Subsequently, the block was compacted by HIP at 750° C. and 1,000 bar to more than 99% of its theoretical density. The structure consisted of the Ag matrix in which Mo agglomerates having a mean particle size of up to 40 μm were embedded. A target of a size of 88×350 mm made from this block was again sputtered. A highly fissured erosion surface was formed very quickly, which was covered with cones and nodules and began to release many particles. This target was also unsuitable for the application.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A sputter target comprising a material having at least two phases, one of the phases being a matrix phase, and at least one minor phase having low solubility in the matrix phase and having a higher melting point than the matrix phase, wherein the at least one minor phase comprises grains or agglomerates formed by its grains having a mean particle size of 10 μm maximum, and wherein the material has a density of at least 98% of its theoretical density.

2. The sputter target according to claim 1, wherein the mean size of the grains or agglomerates is 5 μm maximum.

3. The sputter target according to claim 1, wherein the mean size of the grains or agglomerates is 1 μm maximum.

4. The sputter target according to claim 1, wherein the material has a density of at least 99% of its theoretical density.

5. The sputter target according to claim 1, wherein the at least one minor phase has a melting point which is at least about 500° C. higher than a melting point of the matrix.

6. The sputter target according to claim 1, wherein the at least one minor phase has a melting point which is at least about 1000° C. higher than a melting point of the matrix.

7. The sputter target according to claim 1, wherein the material contains one or more metals selected from the group consisting of W, Mo, Ta, Nb, Cr, V, Ti, Cu, Ni, Al, Ag, Au, Pt, and Ru.

8. The sputter target according to claim 1, wherein the at least one minor phase amounts to at least about 0.5% by weight of the material.

9. The sputter target according to claim 1, wherein the total of the at least one minor phase amounts to about 10% by weight maximum of the material.

10. The sputter target according to claim 1, wherein the material is based on Cu or Ag as the matrix phase, and the at least one minor phase contains at least one of the elements Cr, Mo, W, Ti, and Ru.
